(19) United States
(12) Patent Application Publication
(10) Pub. No.: US 2013/0264620 A1
(43) Pub. Date: Oct. 10, 2013

(54) INTEGRATED CIRCUIT HAVING FERROELECTRIC MEMORY WITH DENSE VIA BARRIER

(71) Applicants: Zhiyi Yu, Allen, TX (US); Ollen Harvey Mullis, Mansfield, TX (US); John Paul Campbell, Dallas, TX (US)

(72) Inventors: Zhiyi Yu, Allen, TX (US); Ollen Harvey Mullis, Mansfield, TX (US); John Paul Campbell, Dallas, TX (US)

(73) Assignee: TEXAS INSTRUMENTS INCORPORATED, Dallas, TX (US)

(21) Appl. No.: 13/441,582

(22) Filed: Apr. 6, 2012

(51) Int. Cl. H01L 29/82; H01L 21/768

(52) U.S. Cl. 257/295; 438/653; 257/E29.323; 257/E21.584

(57) ABSTRACT

A method of forming a barrier/liner for ferroelectric memory capacitors includes chemical vapor depositing 15 to 40 A of a first layer including a refractory metal nitride over a substrate having a plurality of metal-oxide-semiconductor (MOS) gate structures, ferroelectric memory (FeRAM) capacitors, and vias in a dielectric layer overlying the substrate. The first layer is treated using a first plasma treatment including exposing the first layer to a plasma in an atmosphere substantially-free of hydrogen. A 15 to 40 A thick second refractory metal nitride layer is chemical vapor deposited of over the first layer. The second layer is treated using a second plasma treatment including exposing the second layer to a plasma in an atmosphere substantially-free of hydrogen.

### FIELD

Disclosed embodiments relate to integrated circuits (IC) processing, and more particularly to barrier layers for vias comprising refractory metal nitrides used in association with ICs having ferroelectric memory capacitors, and ICs therefrom.

### BACKGROUND

Several trends exist today in the semiconductor device fabrication industry and the electronics industry. Devices are continuously getting smaller and requiring less power. A reason for this is that more personal devices are being fabricated that are small and portable, thereby relying on a small battery as its supply source. For example, cellular phones, personal computing devices, and personal sound systems are devices that are in demand in the consumer market. In addition to being smaller and more portable, personal devices are requiring more computational power and on-chip memory. In light of these trends, there is a need in the industry to provide a computational device that has a fair amount of memory and logic functions integrated onto the same semiconductor chip. This memory should be a non-volatile memory. Examples of conventional non-volatile memory include electrically erasable, programmable read only memory (“EEPROM”) and FLASH EEPROM.

A ferroelectric random access memory (FeRAM) is a type of non-volatile memory that utilizes a ferroelectric material, such as strontium bismuth tantalate (SBT) or lead zirconate titanate (PZT), as the capacitor dielectric situated between a bottom electrode and a top electrode. Both read and write operations are performed for a FeRAM. The memory size and memory architecture affect the read and write access times of a FeRAM.

Ferroelectric memory devices, and other types of semiconductor memories, are used for storing data and/or program code in personal computer systems, embedded processor-based systems, and the like. Ferroelectric memories are commonly organized in single-transistor, single-capacitor (1T1C) or two-transistor, two-capacitor (2T2C) configurations, in which data is read from or written to the device using address signals and various other control signals. The individual memory cells typically comprise one or more ferroelectric capacitors (FeCaps) adapted to store a binary data bit, as well as one or more access transistors, typically metal-oxide-semiconductor (MOS) transistors, operable to selectively connect the FeCap to one of a pair of complimentary bit lines, with the other bit line being connected to a reference voltage. The individual cells are commonly organized as individual bits of a corresponding data word, wherein the cells of a given word are accessed concurrently through activation of plate lines and word lines by address decoding circuitry.

Ferroelectric memory devices provide non-volatile data storage where data memory cells include capacitors constructed with ferroelectric dielectric material that may be polarized in one direction or another in order to store a binary value. The ferroelectric effect allows for the retention of a stable polarization in the absence of an applied electric field due to the alignment of internal dipoles within perovskite crystals in the dielectric material. This alignment may be selectively achieved by application of an electric field to the ferroelectric capacitor in excess of the coercive field of the material. Conversely, reversal of the applied field reverses the internal dipoles. Although the polarization of each individual dipole is relatively small, the net polarization of several domains, each comprising a number of aligned dipoles, can be large enough for detection using, for example, standard sense amplifier designs. The gross effect of polarization is a nonzero charge per unit area of the ferroelectric capacitor that does not disappear over time.

Ferroelectric thin films, such as those made of PZT or SBT, are promising materials for FeRAM use. However, problems remain concerning their integration within the conventional semiconductor processes, including loss of polarization hysteresis characteristics and an increase in leakage current during CMOS processing following FeCap formation that can degrade properties of the ferroelectric layer.

### SUMMARY

Disclosed embodiments include substantially hydrogen (H₂)-free FeRAM ViaO barrier/liner processing that essentially solves the problems of FeRAM ViaO barrier yield loss due to robustness issues, and FeRAM bit cell instability due to hydrogen diffusion into the ferroelectric dielectric material of a FeCap. One embodiment comprises chemical vapor depositing 15 to 40 A of a first layer of a refractory metal nitride, and chemical vapor depositing 15 to 40 A of a second layer of a refractory metal nitride. Post-deposition substantially hydrogen-free plasma treatments of the respective refractory metal nitride layers after their deposition has been discovered to enable a significantly higher level of densification compared to conventional thicker barriers/liners, so that a resulting relative density of disclosed refractory metal nitride barriers/liners average at least 90% across their thickness in the final IC.

As used herein, a “substantially hydrogen-free” environment or one that “substantially excludes hydrogen” is defined herein as having <2% hydrogen partial-pressure, and is typically significantly lower than 2% hydrogen partial-pressure as it is based on the residual amount of H₂ in the chamber set by the pumping capability of the pump for the tool, and “relative density” is defined as the ratio of the actual density of a barrier material to its theoretical (bulk) density. The substantially hydrogen free atmosphere can be provided by flowing nitrogen, or by flowing a noble gas such as Ar, or mixtures thereof.

Both the depositions and plasma treatments can also be performed at a maximum temperature lower than conventional barrier/liner processes, such as from 340° C.-420° C., which has been verified to provide better FeRAM performance compared to conventional higher temperature deposition and plasma treatments (e.g., around 450° C.). The resulting final (densified) thickness of the resulting barrier/liner layer in the final IC is generally from 20 to 54 A when the as-deposited (undensified) thickness for each refractory metal nitride layer is in a range from 15 to 40 A.

### BRIEF DESCRIPTION OF THE DRAWINGS

Reference will now be made to the accompanying drawings, which are not necessarily drawn to scale, wherein:

FIG. 1 is a fragmentary cross-sectional view of a partially fabricated integrated circuit (IC) containing ferroelectric random access memory (FeRAM) capacitors and transistors associated therewith, according to an example embodiment.

FIG. 2 is a flow chart diagram illustrating a method of forming a barrier/liner within a via of a ferroelectric capacitor including forming a first and a second refractory metal nitride layer using a chemical vapor deposition (CVD) process and a plasma treatment substantially excluding hydrogen, in accordance with another example embodiment.

FIGS. 3A and 3B are a scanned transmission electron microscope (TEM) cross-sections for a 2×50 (about 50 A deposited in each of two depositions) related TiN barrier/liner after substantially H₂-free densification treatment and a 2×25 (about 25 A deposited in each of two depositions) disclosed TiN barrier/liner after substantially H₂-free densification treatment, respectively.

FIG. 4 shows data obtained from 1V edge bit polarization switched (Psw) testing for the 2×25 disclosed TiN barrier/liner as compared to the related 2×50 TiN barrier/liner. The 2×25 disclosed TiN barrier/liner is seen to produce significantly higher edge bit Psw as compared to the related 2×50 TiN barrier/liner.

FIG. 5 is test data evidencing a 2×25 disclosed TiN barrier/liner has much lower contact Kelvin resistance as compared to a related 2×50 TiN barrier/liner.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

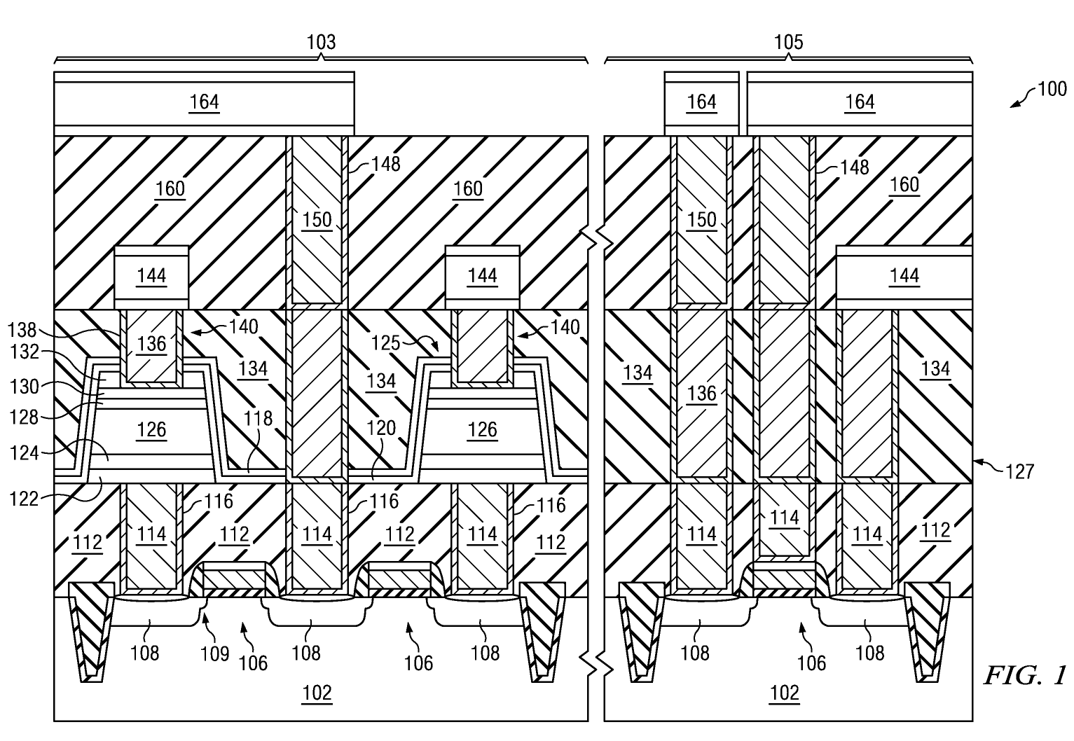

FIG. 1 is a fragmentary cross section of a partially fabricated example IC 100 in which only two devices are illustrated for simplicity, with the understanding the final IC 100 includes many more such devices, as well as a back end of the line (BEOL) metal interconnect stack thereon. While the substrate 102 having a semiconductor surface is typically a single-crystal silicon substrate that is doped n-type or p-type, the substrate 102 may be formed by fabricating an epitaxial silicon layer on a single-crystal silicon substrate, or on another substrate material.

The first device 103 shown represents a partially fabricated version of an FeRAM cell in accordance with a disclosed embodiment, and the second device 105 shown represents a high-voltage transistor, low-voltage transistor, high-speed logic transistor, I/O transistor, analog transistor, or any other device which may be included in a digital signal processor, microprocessor, microcomputer, microcontroller, or any other semiconductor device. Except for the specific cell structure provided in the first device 103, the structures utilized therein may be the same as the device structures of the second device 105 (except for some possible variations in the transistors due to the different device types that second device 105 may be).

Metal-oxide-semiconductor (MOS) gate structures 106 include a gate dielectric (for example, comprising silicon oxide, an oxynitride, silicon nitride, BST, PZT, a silicate, or a high-k material, or any combination or stack thereof), and a gate electrode (for example, comprising polycrystalline silicon doped either p-type or n-type with a silicide formed on top of the gate dielectric, or a metal such as titanium, tungsten, TiN, tantalum, TaN or other type metal). The gate structures 106 generally further comprise side wall insulators (for example, spacers comprising an oxide, a nitride, an oxynitride, or a combination or stack thereof). In general, the generic terms oxide, nitride and oxynitride refer to silicon oxide, silicon nitride and silicon oxy-nitride. The term “oxide” may, in general, include doped oxides as well, such as boron and/or phosphorous doped silicon oxide. The source/drain regions 108 shown may be formed using ion implantation using conventional dopants and processing conditions. Lightly doped drain extensions 109 as well as pocket implants may also be utilized. In addition, the surface of the source/drain regions 108 may be silicided (for example, with titanium, cobalt, nickel, tungsten or other conventional silicide material).

A dielectric layer 112 is formed over the substrate 102 which is patterned and etched so as to form openings for contacts to the substrate 102 and gate structure 106. These openings are filled subsequently with one or more electrically conductive materials, such as a plug 114 (for example, comprising a metal such as tungsten, molybdenum, titanium, titanium nitride, tantalum nitride, or a metal such as Ti, Ni or Co, copper or doped polysilicon). A liner/barrier layer 116 may or may not be formed between the plug 114 and the dielectric layer 112. Such a liner/barrier layer 116 can comprise, for example, Ti, TiN, TaSiN, Ta, TaN, TiSiN, a stack thereof, or any other conventional liner/barrier material. The contacts are formed so as to land on the silicided regions on the surface of the source/drain regions 108 and gate structures 106.

The dielectric layer 112 comprises, for example, SiO₂ (doped or undoped with dopants such as boron or phosphorous), possibly with a layer of hydrogen or deuterium containing silicon nitride next to the gate. After deposition of the liner/barrier layer 116 the barrier layer 116 can be planarized for improved lithography of overlying layers using a process such as chemical mechanical polishing (CMP). In addition, an added diffusion barrier/etch stop (not shown) may be included near the top surface of dielectric layer 112 such as AlOₓ, AlN, Si₃N₄, SiO₂, TiO₂, ZrO₂, or TaOₓ that would be deposited after the planarization process. This diffusion barrier is particularly useful if damascene processes are used to create the via or metallization to the contact. Formation of metal structures that are situated above the contacts is considered to be part of the back end process. Other than the specific FeRAM process module, the back end process steps may be those standard in the semiconductor industry. The metallization may be, for example, either Al-based or Cu-based. The Al is generally etched while the Cu is generally used with CMP in a damascene approach. However, etching Cu and Al formed in a damascene process is also possible. According to one example, aluminum metallization will have CVD tungsten plugs or Al plugs, and the Al will be Cu-doped for improved electromigration resistance. Metal diffusion barriers for Al may include, for example, TiN and/or Ti. Copper metallization may have, for example, Cu or W via-fill materials with either Ti, TiN, TiSiN, Ta, tantalum nitride, and/or TaSiN diffusion barriers.

A thin dielectric layer (not shown) may be formed between each of the interlevel dielectric (ILD) layers (layers 112, 134 and 160). If formed, this thin dielectric layer can comprise, for example, silicon nitride, silicon carbide, SiCNO or a silicon oxide (for example, a high-density plasma enhanced process provided silicon oxide). In addition, interlevel dielectric layers 112, 134, and 160 may comprise, for example, an oxide, FSG, PSG, BPSG, PETEOS, HDP oxide, a silicon nitride, silicon oxynitride, silicon carbide, silicon carbo-oxy-nitride, a low dielectric constant material (for example, SiLK, porous SiLK, teflon, low-K polymer (possibly porous), aerogel, xerogel, BLACK DIAMOND, HSQ, or any other porous glass material), or a combination or stack thereof.

The interconnects and the metal lines can comprise the same material. Via fill material 136 and 150 and conductors 144 and 164 can comprise a metal material (for example, copper, aluminum, titanium, TiN, tungsten, tungsten nitride, or any combination or stack thereof). Although not shown, for a copper damascene process where conductor 164 comprises copper, via fill material 150 would be replaced by conductor 164.

A barrier/liner is generally formed between the via fill material 136 and the respective interlevel dielectric layer. The barriers/liners (shown as layers 138 and 148) can comprise, for example, Ti, TiN, W, WN, Ta, TaN, any conventional barrier/liner, or any combination or multi-layer stack thereof. For example, the barriers/liners may be a single TiN barrier layer, or a multi-layer stack of Ti and TiN barrier/liner layers. When the via fill material 136 and the barrier/liner 138 is formed within ILD layer 134, they form a structure which is referred to herein as a VIA0 140.

The materials for ILD 134 and the via fill material 136 should be selected to be compatible with the FeRAM thermal budget. With existing technology (i.e., for example, one that incorporates via fill material 136 comprising W and SiO₂ ILD 134), the FeRAM thermal budget should generally be less than approximately 600 or 650° C., however, disclosed embodiments are not limited thereto. If the ILD 134 is modified to include a low dielectric constant (“low-k”) layer, the FeRAM thermal budget be reduced further.

Level 127 is added so as to accommodate the FeRAM cells (FeRAM process module). This FeRAM process module allows the creation of ferroelectric or high dielectric constant capacitors to be easily added with maximum thermal budget for the new process module yet not impact the thermal budget of the backend process. In particular, this level allows FeRAM devices with capacitor under bit line configuration compatible with a high-density memory. However, it is possible, if planarity is not a necessity, to form the FeRAM devices while not forming level 127 in region 105. Hence, the first device 103 having the FeRAM portion would be taller than the second device 105 having the MOS portion by the height of level 127.

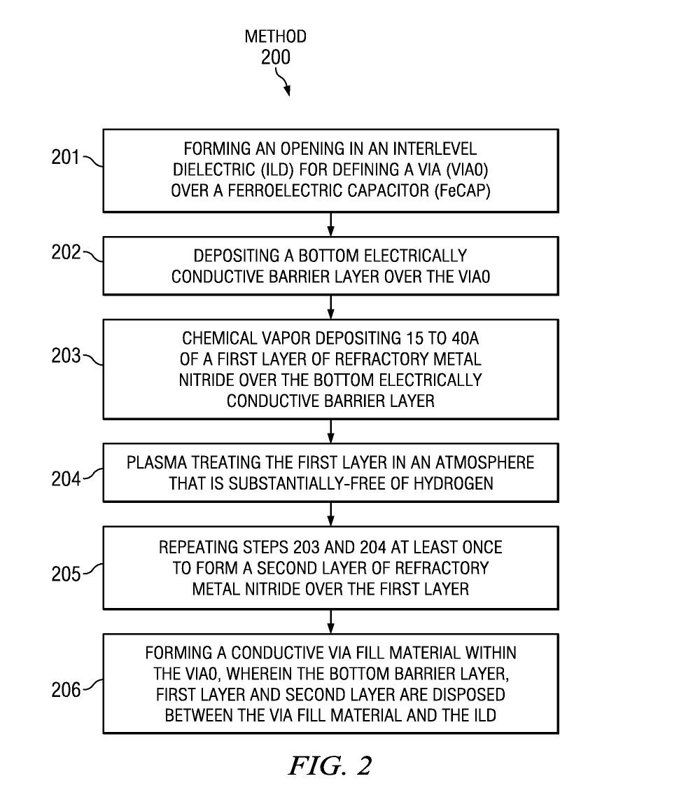

Initially, a further discussion of FIG. 1 will be provided to appreciate the structure of an FeRAM cell and an example integration position of such a cell within a semiconductor fabrication process. Subsequently, a flow chart (FIG. 2) will be provided to illustrate an example method for fabricating a VIA0 140 over such an FeRAM cell in order to provide a context in which certain disclosed embodiments may reside. In conjunction therewith, disclosed embodiments will be described and illustrated in greater detail. It should be understood, however, that although disclosed embodiments will be shown and described in conjunction with one example context, disclosed embodiments are applicable to other fabrication methodologies, structures and materials, and such alternatives are contemplated as falling within the scope of this Disclosure.

An FeRAM capacitor, as illustrated in FIG. 1 as reference numeral 125, resides above the interlayer dielectric 112, and comprises several layers. The FeRAM capacitor 125 of FIG. 1 comprises an electrically conductive barrier layer 122 upon which an electrically conductive bottom capacitor electrode 124 resides (hereinafter, the terms “conductive” and “insulative” if unqualified indicate electrically conductive and electrically insulative, respectively, unless indicated otherwise). A list of example electrode materials includes Pt, Pd, PdOx, Ir, IrPt alloys, Au, Ru, RuOx, (Ba,Sr,Pb)RuO₃, (Sr,Ba,Pb)IrO₃, Rh, RhOx, LaSrCoO₃, (Ba,Sr)RuO₃, and LaNiO₃. A capacitor dielectric layer 126 comprising a ferroelectric material, is formed over the bottom electrode 124, and is covered by, for example, a conductive multi-layer top electrode 128, 130. A top portion of the FeRAM capacitor 125 comprises a hard mask layer 132 that may be employed to facilitate forming the capacitor stack etch. The capacitor stack may then be covered with a single or multi-layer sidewall diffusion barrier 118, 120.

An example method of forming a via in the proximity of an FeRAM capacitor in accordance with an example embodiment which is similar in many respects to the VIA0 140 and the capacitor 125 of FIG. 1, will now be discussed in conjunction with FIG. 2. FIG. 2 is a flow chart diagram illustrating a method 200 of forming a barrier/liner 138 including two or more refractory metal nitride layers in a via of a ferroelectric capacitor using a chemical vapor deposition process and a plasma treatment substantially excluding hydrogen, in accordance with another example embodiment.

Prior to the beginning of the method 200, a FeRAM capacitor 125 is formed, including an interlevel dielectric 134 over the FeRAM capacitor 125 and an opening in the ILD 134 defining the via, as noted above referred to herein as VIA° when lined by barrier/liner 138 and then filled by via fill material 136. Step 201 comprises forming an opening in the ILD defining a via for VIA° over a ferroelectric capacitor (FeCAP). The opening may be cleaned by an argon pre-sputter cleaning, which can clean the interface (e.g., removes any interfacial oxide or other contaminates) to reduce the resistance of the resultant via/top electrode interface/contact.

At step 202, an electrically conductive bottom barrier layer (e.g., a 200 A thick layer of Ti) is deposited over the VIA° opening. Step 203 comprises chemical vapor depositing a first electrically conductive refractory metal nitride barrier/liner layer over the bottom barrier layer. The first refractory metal nitride barrier/liner layer can be deposited by low pressure chemical vapor deposition (LPCVD) including PECVD, or atmospheric CVD. Example refractory metal nitrides that can be deposited by CVD include TaN, HfN, ZrN, TiN and VN. Disclosed embodiments also include ternary refractory metal nitrides. The first barrier/liner layer then receives a plasma treatment at 204 in an atmosphere that is substantially-free of hydrogen which results in densification to provide a TiN thickness of 10 to 27 A.

In one example cycle, the plasma treatment can comprise about 300 to 800 sccm N₂, at a temperature of about 340 to 420° C., at 500 to 1,000 watts of power, for about 40 to 60 seconds. The plasma treatment has been found to provide a densification across the full thickness of the refractory metal nitride barrier/liner layer so that a relative density of the refractory metal nitride layer averages at least 90% across its thickness, and in some embodiments the relative density averages >93%.

For example, for a TiN layer, an average relative density of at least 90% translates to a density of at least 4.89 g/cm³, since the density of TiN as a bulk material is 5.043 g/cm³ (CRC Materials Science and Engineering Handbook, p. 50-52). Accordingly, the thickness of the refractory metal nitride barrier/liner layer has been discovered to be a results effective variable when the refractory metal nitride barrier/liner layer is thin enough to allow it to be fully densified, found to be surprisingly possible even at a reduced plasma treatment temperature of 340° C. to 420° C.

At step 205, steps 203 and 204 are repeated at least once to form a second electrically conductive refractory metal nitride barrier/liner layer on the first refractory metal nitride barrier/liner layer. The parameters disclosed above for steps 203 and 204 can also be used for step 205. The second refractory metal nitride barrier/liner layer can also be deposited by LPCVD, including PECVD, or atmospheric CVD.

The final (combined) thickness for the refractory metal nitride barrier/liner portion of barrier/liner 138 (sum of the first and second refractory metal nitride barrier/liner layers) is 20 to 54 A. At step 206, an electrically conductive via fill material is formed in the via over the barrier/liner 138 to complete VIA0, for example, a via fill material 136 comprising tungsten is formed in the via, wherein the barrier/liner 138 is disposed between the via fill material 136 and the ILD 134 to avoid reaction of the tungsten deposition process gasses with the underlying films. Alternatively, if the via fill material 136 is copper, the barrier/liner 138 serves to prevent out-diffusion of the copper (or other via fill material) into the ILD 134. Thereafter, a backend process may continue for forming other ILD layers and contacts of the ferroelectric device. For a CVD deposited barrier/liner 138, in the finished IC, the barrier/liner 138 contains on average through its thickness between 0.001 to 0.2 wt. % carbon, which is indicative of almost complete removal of carbon resulting from the hydrocarbon precursor used in the CVD processes to form the barrier/liner layer.

For tests run, wafers having FeRAM capacitors including 2×25 disclosed TiN ViaO barriers/liners (2×25 disclosed TiN barriers/liners) were fabricated. The process sequence used was a thermal degas under heat lamps to remove moisture from the ViaO, followed by an argon sputter etch. About 200 A of Ti was then deposited by sputtering to provide a bottom barrier layer. The first refractory metal nitride barrier/liner layer PECVD deposition and substantially hydrogen free plasma treatment, were both performed at 380° C., which included depositing approximately 25 A of untreated PECVD TiN, then in a nitrogen ambient which does not contain measurable H₂. The TiN film was plasma treated so that it densified down to a thickness of approximately 16.5 A. A second untreated PECVD TiN barrier/liner layer of approximately 25 A was then deposited. In a nitrogen ambient which does not contain measurable H₂ the second barrier/liner layer was plasma treated so that it densified down to a thickness of approximately 16.5 A. Accordingly, the final total TiN barrier/liner thickness was about 33 A. The densified TiN barrier/liner layer was found to have a measured density of 5.1 g/cm³ by x-ray reflectivity (XRR). Thus, using a theoretical density of 5.4 g/cm³ for TiN, the relative density of the 2×25 disclosed TiN barrier/liner was found to be about 94.4%

For controls, wafers having FeRAM capacitors including 2×50 TiN ViaO barriers/liners (related 2×50 barriers/liners) were also fabricated. A thermal degas under heat lamps was used to remove moisture from the ViaO, followed by an argon sputter etch, which was followed by about 200 A of Ti deposited by sputtering. The first and second barrier/liner deposition were both PECVD. The barrier/liner depositions and the substantially hydrogen free plasma treatments were both performed at 380° C. The plasma treatment provided limited densification of the barrier/liner layers so that the final thickness of TiN was about 80 A. The related 2×50 TiN barrier/liner layer was found to have a measured density of 3.7 to 4.1 g/cm³, or 68% to 76% of the theoretical density of 5.4 g/cm³ for TiN.

Tests were performed to compare the 2×25 disclosed TiN barrier/liner vs. the related 2×50 barrier/liner, including FeRAM capacitors therefrom. As described below, a clear and significant improvement was shown for barrier robustness for the 2×25 disclosed TiN barrier/liner as compared to the related 2×50 TiN barrier/liner in terms of physical properties, electrical properties as well as multi-probe yield.

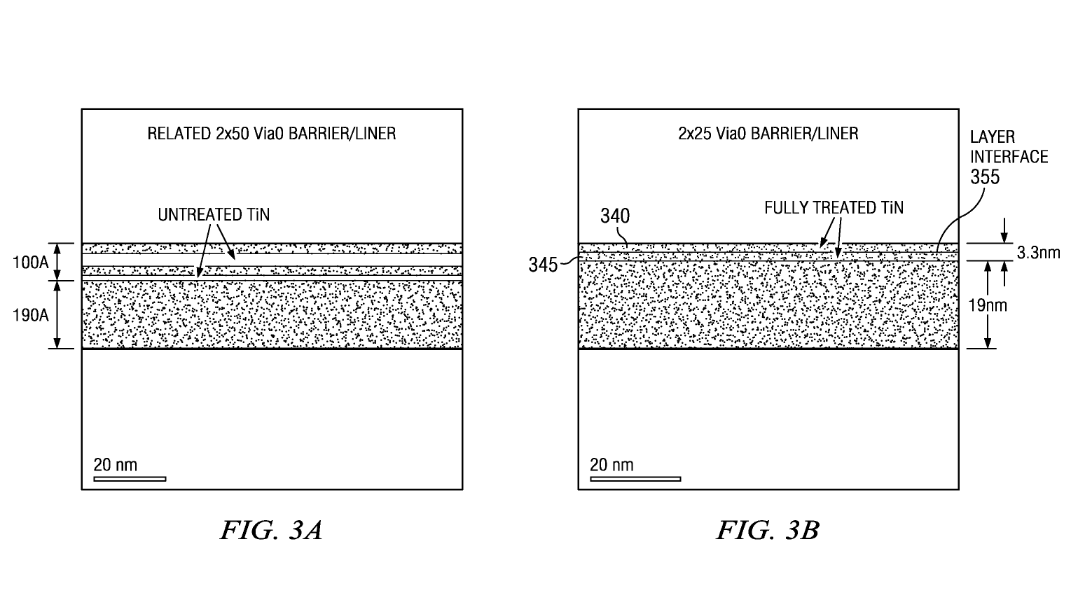

FIGS. 3A and 3B are scanned TEM cross-sections for the related 2×50 (about 50 A deposited in each of two depositions) TiN barrier/liner after densification treatment in 1.3 Torr N₂ plasma at 750 W for 50 seconds and 2×25 (about 25 A deposited in each of two depositions) disclosed TiN barrier/liner after densification treatment in 1.3 Torr N₂ plasma at 750 W for 50 seconds, respectively. The bottom barrier layer shown in both FIGS. 3A and 3B is a 190 A thick titanium (Ti) layer.

The respective TiN barrier/liner layers in FIG. 3A each show regions of “untreated TiN” which corresponds to largely undensified TiN, that have a relative density of about 60% which corresponds to the relative density of as-deposited CVD TiN. In FIG. 3B the first and second TiN barrier/liner layers 345 and 340 each show essentially full densification, having a relative density of about 94 to 95% based on the relative density data from XRR described above, with no evidence of any untreated (largely undensified) TiN regions, such as the undensified regions clearly evident in FIG. 3A. In FIG. 3B, a narrow layer interface 355 is depicted between the first refractory metal nitride barrier/liner layer 345 and the second refractory metal nitride barrier/liner layer 340 that represents the resulting structure from use of the first and second chemical vapor depositions described above relative to method 200 when used to form disclosed refractory metal nitride barrier/liner layers.

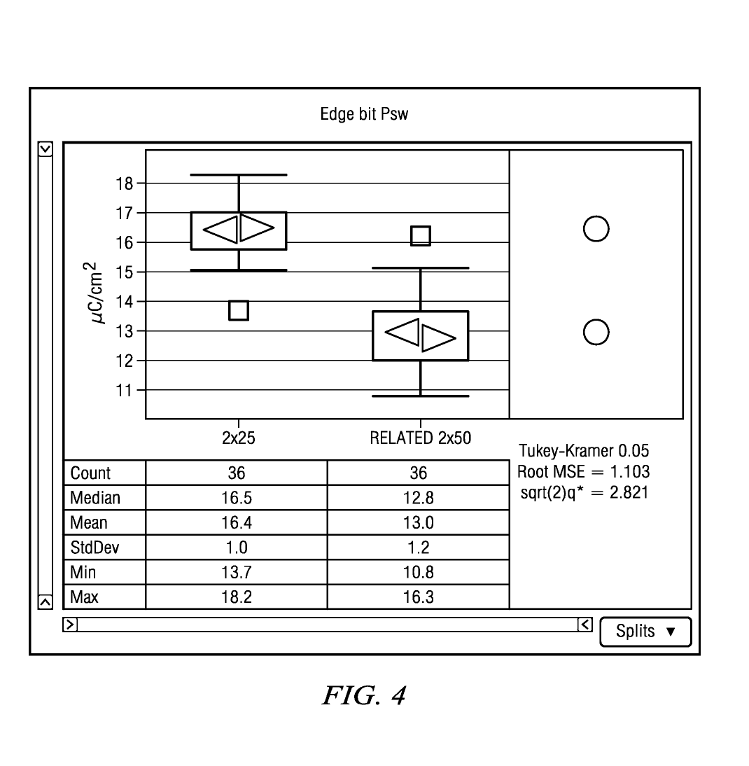

FIG. 4 shows data obtained from 1V edge bit polarization switched (Psw) testing for the 2×25 disclosed TiN barrier/liner as compared to the related 2×50 TiN barrier/liner. Edge bit Psw is known to be degraded due to hydrogen damage, which can occur to FeRAM capacitors in fab processing following FeRAM capacitor formation. The 2×25 disclosed TiN barrier/liner is seen to produce significantly higher edge bit Psw as compare to the related 2×50 TiN barrier/liner, showing the related 2×50 TiN barrier/liner is vulnerable to hydrogen damage, while the 2×25 disclosed TiN barrier/liner is significantly resistant to hydrogen damage.

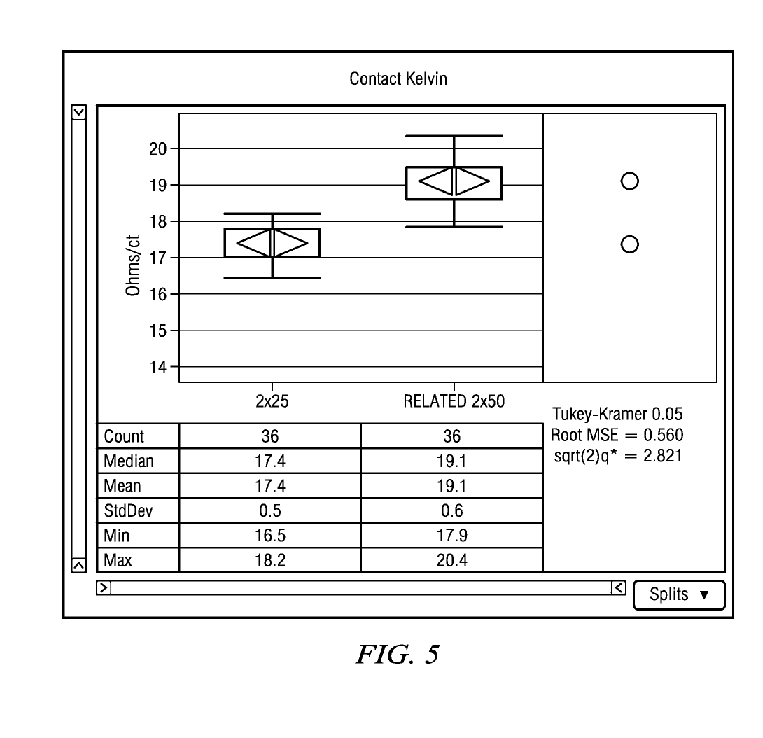

FIG. 5 is test data evidencing a 2×25 disclosed TiN barrier/liner has much lower contact Kelvin resistance as compared to a related 2×50 TiN barrier/liner. Multiprobe and 2T2C yield were also compared between the 2×25 disclosed barrier/liner and the related 2×50 barrier/liner. Multiprobe yields were generally 13% to 30% higher for the 2×25 disclosed TiN barrier/liner as compared to the related 2×50 TiN barrier/liner, and substantially more consistent 2T2C yield was also shown.

Disclosed embodiments can be integrated into a variety of process flows to form a variety of different semiconductor IC devices and related products. The die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A method of forming a barrier/liner layer for ferroelectric memory capacitors, comprising:
chemical vapor depositing 15 to 40 A of a first layer of refractory metal nitride over a substrate having a plurality of metal-oxide-semiconductor (MOS) gate structures, ferroelectric memory (FeRAM) capacitors, and vias in a dielectric layer overlying said substrate,
treating said first layer using a first plasma treatment comprising exposing said first layer to an atmosphere substantially-free of hydrogen;
chemical vapor depositing 15 to 40 A of a second layer of a refractory metal nitride over said first layer, and
treating the second layer using a second plasma treatment comprising exposing said second layer to an atmosphere substantially-free of hydrogen.

2. The method of claim 1, wherein said refractory metal nitride comprises titanium nitride.

3. The method of claim 1, wherein said refractory metal nitride comprises tantalum nitride.

4. The method of claim 1, wherein said chemical vapor depositing said first layer and said second layer both comprise low-pressure chemical vapor deposition (LPCVD).

5. The method of claim 1, wherein said chemical vapor depositing said first layer and said second layer both comprise plasma enhanced chemical vapor deposition (PECVD).

6. The method of claim 1, wherein said first plasma treatment and said second plasma treatment provide a densification of said first layer and said second layer so that a relative density of said barrier/liner layer averages at least 90% across its thickness.

7. The method of claim 1, wherein said first plasma treatment and said second plasma treatment are both performed at a maximum temperature between 340° C. to 420° C.

8. The method of claim 1, further comprising:
cleaning a bottom surface of said via using an argon sputter etch; and
depositing a titanium layer in said vias prior to said depositing said first layer.

9. The method of claim 1, wherein said first plasma treatment and said second plasma treatment are performed in a nitrogen or noble gas containing atmosphere.

10. A method of forming a barrier/liner layer for ferroelectric memory capacitors, comprising:
chemical vapor depositing 15 to 40 A of a first layer of titanium nitride over a substrate having a plurality of metal-oxide-semiconductor (MOS) gate structures, ferroelectric memory (FeRAM) capacitors, and vias in a dielectric layer overlying said substrate,
treating said first layer using a first plasma treatment comprising exposing said first layer to a nitrogen or noble gas containing plasma in an atmosphere substantially-free of hydrogen;
chemical vapor depositing 15 to 40 A of a second layer of titanium nitride on said first layer, and
treating the second layer using a second plasma treatment comprising exposing said second layer to a nitrogen or noble gas containing plasma in an atmosphere substantially-free of hydrogen,
wherein said chemical vapor depositing said first layer, said first plasma treatment, said chemical vapor depositing said second layer, and said second plasma treatment are all performed at a maximum temperature between 340° C. to 420° C.

11. An integrated circuit (IC), comprising:
a substrate having a semiconductor surface;
a metal-oxide-semiconductor (MOS) transistor including a MOS gate structure on said semiconductor surface having a source and a drain lateral to said MOS gate structure;
an interlevel dielectric (ILD) layer over said gate structure;
a ferroelectric memory device including a ferroelectric memory capacitor comprising a bottom electrode, a capacitor dielectric layer comprising a ferroelectric material, and a top electrode,
a via in said ILD above said top electrode;
a barrier/liner comprising a refractory metal nitride lining said via, and
a via fill material filling said via over said barrier/liner,
wherein said refractory metal nitride is 20 A to 54 A thick, has a relative density that averages at least 90% across its thickness, and comprises at least two refractory metal nitride layers having an interface therebetween.

12. The IC of claim 11, wherein said refractory metal nitride comprises titanium nitride.

13. The IC of claim 11, wherein said refractory metal nitride comprises tantalum nitride.

14. The IC of claim 11, wherein said refractory metal nitride contains on average through its thickness between 0.001 to 0.5 wt. % carbon.

15. The IC of claim 11, wherein said relative density is at least 93%.

16. The IC of claim 11, wherein said barrier/liner further comprising a layer of titanium beneath said refractory metal nitride.

17. The IC of claim 11, wherein said via fill material comprises tungsten.
